(19) United States
(12) Patent Application Publication
(10) Pub. No.: US 2008/0164613 A1
(43) Pub. Date: Jul. 10, 2008

(54) ULTRA-THIN Cu ALLOY SEED FOR INTERCONNECT APPLICATION

(75) Inventors: Daniel C. Edelstein, White Plains, NY (US); Stephen M. Rossnagel, Pleasantville, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/621,709

(22) Filed: Jan. 10, 2007

(51) Int. Cl. H01L 23/48; H01L 21/288

(52) U.S. Cl. 257/753; 438/654; 257/E23.011; 257/E21.175

(57) ABSTRACT

A copper interconnection structure which is electroplated onto a silicon layer or semiconductor substrate. The structure includes an ultra-thin copper seed alloy incorporating selectively minor amounts of a dopant material to facilitate a continuous deposition thereof onto the silicon layer or semiconductor substrate. The copper seed alloy may contain dopant material selected from the group of materials consisting of Ru, Ir, Pt, Pd and alloys thereof. Furthermore, there is provided a method for producing the structure.

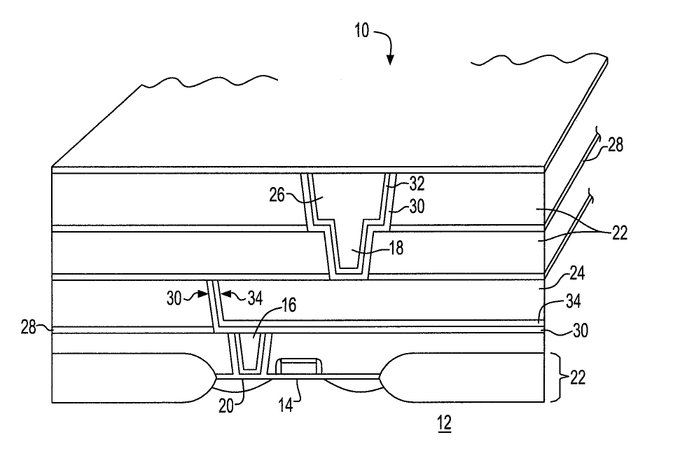

### BACKGROUND OF THE INVENTION

1. Field of the Invention

The present invention relates to a copper interconnection structure on a semiconductor wafer incorporating an ultra-thin copper alloy seed for interconnect applications.

The usage of a thin Cu seed layer to facilitate electroplating has been known for a lengthy period of time in the technology. In practical production terms, this layer is usually sputtered into or onto an interconnect structure after the depositing of a barrier layer. Subsequent to the seed layer deposition, the wafer is electroplated to fill trenches and vias which are provided in the interconnect features. A basic fundamental problem, which is encountered with the Cu seed layer, is that it is prone to agglomeration, which is driven by the temperature of the wafer surface. This phenomenon can be controlled to some degree by extensive wafer cooling; however, this adds time to the process, increases the cost to the eventual deposition, and imparts a complexity (and attendant cost) to the processing tools. In the state of the technology, as circuit dimensions continue to be reduced or miniaturized, it is necessary to scale the thickness of the Cu seed layer down to ever-thinner levels. However, as the film thickness is reduced, it becomes more prone to forming a discontinuous film, which then will result in void formations after electroplating. It is of important interest to be able to deposit a Cu seed layer which can be made continuous at very thin levels. Thinner copper films result in savings to process time and cost, and facilitate plating into ever-smaller features.

2. Discussion of the Prior Art

In the prior art, a solution which has been proposed in order to ameliorate the foregoing problems, resides in the utilization of a barrier layer, which also facilitates Cu electroplating. Potential materials, which would be applicable for that purpose, would also be Pt, Ir and Ru; however, each of these materials must satisfy stringent requirements for circuit performance and reliability and at this time, there is no adequate assurance that these materials will be viable or practical for satisfactory interconnect manufacturing processes and applications.

In order to attain further advantages over the art, pursuant to the invention there is presently suggested a new utilization of a dilute alloy of Cu to reduce agglomeration of the deposited copper alloy seed layer.

### SUMMARY OF THE INVENTION

The use of dopants in materials such as Cu and Al has long been known, although they have never been adapted to the presently intended specific purpose. Generally, utilized are two levels of the doping process. At very low levels, the Cu tends to form a fine-grained structure that would be continuous at very small thicknesses compared to pure Cu. This would allow electroplating on surfaces with very thin seed layers that currently cannot be implemented with pure Cu seed layers. Alternatively, the Cu can be mixed with a much larger fraction of the dopant material, such as 30-50%, whereby in that case, the dopant material would need to be a platable material, such as Ru, Ir, Pt, Pd, etc. This alloy material is deemed to be metastable at room temperature, since the solubility of those materials in Cu is very low. However, if they were deposited by co-sputtering, a 50-50 alloy could be made. It is probable that this material would not have a clear microstructure and would be effectively amorphous. In this case, electroplating would occur as before, but the plated films could have much larger grain size than that for conventional Cu seed or lightly-doped Cu seed layers.

### BRIEF DESCRIPTION OF THE DRAWING

Reference may now be made to the following detailed description of an embodiment of the invention, taken in conjunction with the accompanying single drawing figure showing an enlarged perspective view of an electronic structure having an interconnection system built therein.

### DETAILED DESCRIPTION OF THE INVENTION

Referring, in particular, to the drawing, there is shown an enlarged, perspective view of an interconnection structure 10. The interconnection structure 10 is built on a substrate 12 which may be silicon or other semiconductor material in which electronic devices are contained. The device 14 with suitable studs and local interconnections 16 are built on semiconductive substrate 12. Vertical connections between wiring levels are provided by Cu stud structure 18 and W stud structure which connect the wiring to the device contact 64. The device 66 shown generally represents a CMOS transistor, but may be any electronic device.

To prevent diffusion of copper into the insulators 22 or device 14, diffusion/adhesion barrier layers are normally used to surround the copper 24, 18, and 26. The diffusion/adhesion barrier layers may be insulating layers 28 or conducting layers 30. The conducting diffusion barrier layer 30 also provides adhesion for the copper to the underlying materials, even though they are referred to as simply in this document as the barrier layer. Also shown in the drawing figure, are the seed layers 32 and 34, which are normally deposited under the main copper conductor layers 24, 18 and 26. The locations and functions of the seed layers may be described with reference to two known methods of fabricating the interconnection structures, i.e., a single Damascene process and a dual Damascene process.

Concerning the foregoing, a more detailed description of the structure is elucidated in Edelstein, et al., U.S. Pat. Nos. 6,181,012 B1 and 6,399,496 B1, both of which publications are assigned to the common assignee of the present application, and the disclosures of which are incorporated herein by reference in their entireties.

With regard to the utilization of invention, there is also contemplated a modification with regard to the state-of-the-art in that a layer of Cu, which is slightly doped with another metal, as described in the above-mentioned prior art publications, and which replaces the pure Cu seed layer.

This metal should have a very low solubility in Cu, such that during temperature cycling steps, which are part of the manufacturing process, the dopant does not move readily through the Cu. An example of a relevant dopant is Ru. A material such as that is also compatible with the electroplating technology, and as a result there is no change required in carrying out the electroplating process. Heavily-doped seed layers can be made with the same procedure, and would result in poorly- or non-crystallized seed layers.

In summation, the foregoing provides an improvement in the provision of interconnect applications for copper interconnecting structures through the use of the novel ultra-thin Cu alloy seed, as provided for herein.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but to fall within the spirit and scope of the appended claims.

What is claimed is:

1. A copper interconnection structure which is electroplated onto a silicon layer or semiconductor substrate, wherein said structure comprises an ultra-thin copper seed alloy incorporating selectively minor amounts of a dopant material to facilitate a continuous deposition thereof onto the silicon layer or semiconductor substrate.

2. A copper interconnection structure as claimed in claim 1, wherein said copper seed alloy contains dopant material selected from the group of materials consisting of Ru, Ir, Pt, Pd and alloys thereof.

3. A copper interconnection structure as claimed in claim 1, wherein said dopant material is added to the copper seed alloy in amounts between 0 to about 50% by weights.

4. A copper interconnection structure as claimed in claim 2, wherein said copper seed alloy and dopant material are deposited by co-sputtering onto said silicon layer or semiconductor substrate.

5. A method of producing a copper interconnection structure comprising electroplating a copper composition onto a silicon layer or semiconductor substrate, wherein said copper composition comprises an ultra-thin copper seed alloy incorporating selectively minor amounts of a dopant material to facilitate a continuous deposition thereof onto the silicon layer or semiconductor substrate.

6. A method as claimed in claim 1, wherein said copper seed alloy contains dopant material selected from the group of materials consisting of Ru, Ir, Pt, Pd and alloys thereof.

7. A method as claimed in claim 1, wherein said dopant material is added to the copper seed alloy in amounts between 0 to about 50% by weights.

8. A method as claimed in claim 2, wherein said copper seed alloy and dopant material are deposited by co-sputtering onto said silicon layer or semiconductor substrate.
